(19) United States
(12) Patent Application Publication
(10) Pub. No.: US 2015/0100609 A1
(43) Pub. Date: Apr. 9, 2015

(54) COMPRESSION OF TIME-VARYING SIMULATION DATA

(71) Applicant: Brigham Young University, Provo, UT (US)

(72) Inventors: Trevor Blanc, San Diego, CA (US); Steve Gorell, Spanish Fork, UT (US); Matthew Jones, Provo, UT (US); Earl Duque, Prescott, AZ (US)

(21) Appl. No.: 14/508,104

(22) Filed: Oct. 7, 2014

Related U.S. Application Data
(60) Provisional application No. 61/887,852, filed on Oct. 7, 2013.

(51) Int. Cl. H03M 7/30; G06F 17/14

(52) U.S. Cl. CPC H03M 7/30; H03M 7/3059; G06F 17/147; G06F 17/141
USPC 708/203

(57) ABSTRACT

A method, executed by at least one processor, for compressing time-varying scientific data, includes receiving time-varying data corresponding to a physical phenomenon within a domain comprising one or more spatial dimensions, conducting a proper orthogonal decomposition of the time-varying data to provide basis vectors for the time-varying data, generating a set of expansion coefficients corresponding to the basis vectors that are most prominent in the time-varying data, conducting an image compression algorithm on the expansion coefficients to provide a compressed representation of the time-varying data, and storing the compressed representation of the time-varying data. The time-varying data may be numeric data generated from a physical simulation or from experimentation. In some embodiments, the time-varying data corresponds to one or more sub-domains within a larger dataset. The sub-domains may be coherent sub-domains that have similar modes. A corresponding computer-program product and computing system are also disclosed herein.

### CROSS-REFERENCE TO RELATED APPLICATIONS

This application claims the benefit of U.S. provisional application 61/887,852 entitled “Proper Orthogonal Decomposition Compression Method” and filed on 7 Oct. 2013. The foregoing application is incorporated herein by reference.

### BACKGROUND

The subject matter disclosed herein relates generally to systems and methods for storing time-varying simulation data.

Contemporary computer simulations that are used to analyze and engineer products generate massive amounts of time-varying data that must be stored to facilitate review and analysis. What is needed are methods and systems that provide improved compression of the data from those simulations.

### SUMMARY OF THE INVENTION

As disclosed herein a method, executed by at least one processor, for compressing time-varying scientific data includes receiving time-varying data corresponding to a physical phenomenon within a domain comprising one or more spatial dimensions, conducting a proper orthogonal decomposition of the time-varying data to provide basis vectors for the time-varying data, generating a set of expansion coefficients corresponding to the basis vectors that are most prominent in the time-varying data, conducting an image compression algorithm on the expansion coefficients to provide a compressed representation of the time-varying data, and storing the compressed representation of the time-varying data.

The time-varying data may be numeric data generated from a physical simulation. In some embodiments, the time-varying data corresponds to one or more sub-domains within a larger dataset. The sub-domains may be coherent sub-domains that have similar modes. The image compression algorithm may comprise a sinusoidal transform or a wavelet transform. In one embodiment, the image compression algorithm is JPEG compliant. A corresponding computer-program product and computing system are also disclosed herein.

### BRIEF DESCRIPTION OF THE DRAWINGS

The accompanying drawings, which are incorporated in and constitute a part of the specification, illustrate one or more embodiments and, together with the description, explain these embodiments. In the drawings:

FIG. 1 is a flowchart depicting one embodiment of a scientific data compression method of the present invention;

FIG. 2 is a graph depicting example expansion coefficients as a function of the time step in accordance with the present invention;

FIG. 3 is a set of intensity plots depicting the first nine POD modes for one compression example in accordance with the present invention;

FIG. 4 is a perspective view illustration depicting the concept of sub-domain partitioning in accordance with the present invention;

FIG. 5 is a cross-sectional view illustration depicting the benefits of sub-domain coherency in accordance with the present invention;

FIG. 6 is a table depicting the effect of sub-domain partitioning on various performance metrics for one compression example; and

FIG. 7 is a graph depicting the effect of sub-domain partitioning on reconstruction error in accordance with the present invention.

### DETAILED DESCRIPTION

The present invention provides improved compression of scientific data such as data generated from experiments, observation and computer simulations.

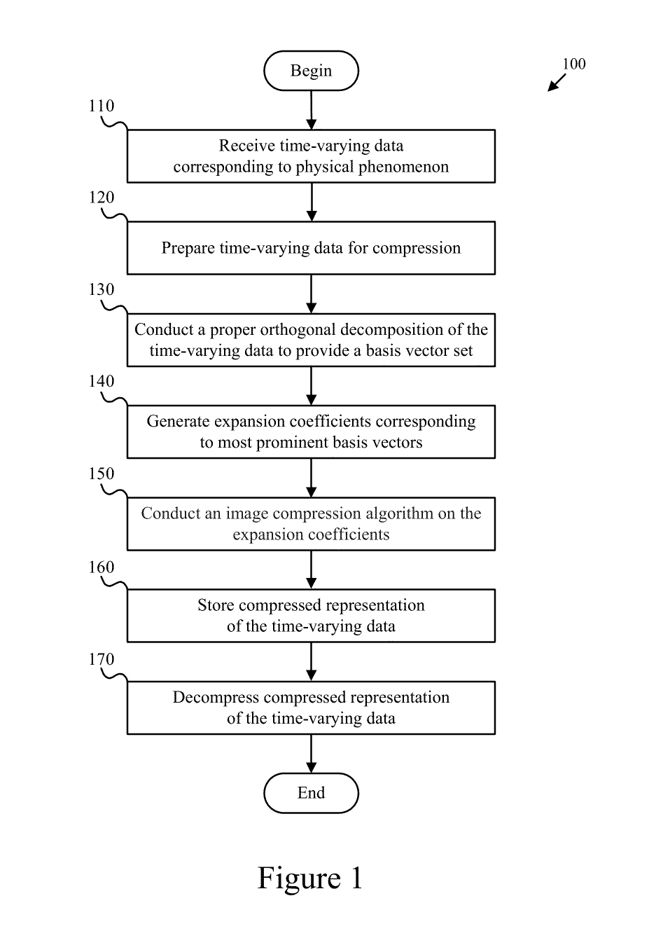

FIG. 1 is a flowchart depicting one embodiment of a scientific data compression method 100 of the present invention. As depicted, the compression method 100 includes receiving (110) time-varying data, preparing (120) the time-varying data for compression, conducting (130) a proper orthogonal decomposition, generating (140) expansion coefficients, conducting (150) an image compression algorithm, storing (160) a compressed representation of the time-varying data, and decompressing (170) the compressed representation of the time-varying data. The compression method 100 provides improved compression of time-varying scientific data over conventional compression methods.

Receiving (110) time-varying data may include receiving time-varying data corresponding to a physical phenomenon. Examples of physical phenomenon that can be represented with time-varying data include heat transfer, fluid flow, electromagnetic propagation, mechanical dynamics, and the like. The time-varying data may have one or more spatial dimensions in which a time varying physical phenomenon occurs. The time-varying data may also have a temporal dimension or one or more spatial dimensions such as rotation angle that correspond to a progression in time for the physical phenomenon. In some embodiments, the time-varying data is numeric data generated from physical simulation, observation, or experiment. The numeric data may have a level of precision that is arbitrarily higher than the precision available in compressed image files.

Preparing (120) the time-varying data for compression may include de-trending the time-varying data by subtracting the mean and slope of the data over time. In some embodiments, the time-varying data is partitioned into sub-domains for processing. In certain embodiments, data corresponding to multiple coherent sub-domains is processed as a single dataset. For example, specific regions of data in the original dataset that are highly correlated may be prepared to be processed as a single (multiple sub-domain) dataset.

Conducting (130) a proper orthogonal decomposition (POD) may include using methods know in the art such as, principle component analysis, modal analysis or the Karhunen-Loeve decomposition that are based on a statistically optimal set of orthogonal basis vectors. The orthogonal basis vectors may also be generated using a matrix decomposition method such as the singular value decomposition or the eigenfunction method. The orthogonal basis vectors may correspond to modes in the time-varying data. The orthogonal basis vectors may be sorted in order of the magnitude of the associated singular value or eigenvalue.

Generating (140) expansion coefficients may include selecting the most prominent basis vectors and generating expansion coefficients corresponding to those basis vectors.

Conducting (150) an image compression algorithm may include conducting a sinusoidal transform or a wavelet transform on the expansion coefficients to provide transformed data. Examples of a sinusoidal transform include a discrete fourier transform, a discrete cosine transform, and a discrete sine transform. The transformed data may be quantized and bit encoded to provide a compressed representation of the time-varying data. The transformed data may be scaled in conjunction with quantization in order to use the entire dynamic range of the quantized representation. In some embodiments, the image compression algorithm is JPEG compliant.

In certain embodiments, all of the basis vectors are also transformed and bit encoded and included in the compressed representation of the time-varying data. In some embodiments, only the basis vectors are transformed and bit encoded and included in the compressed representation of the time-varying data. In other embodiments, the most prominent basis vectors are shared for multiple sets of time-varying data and not included in each compressed representation.

Storing (160) the compressed representation of the time-varying data may include storing the compressed representation of the time-varying data within a memory device for subsequent retrieval. Decompressing (170) the compressed representation of the time-varying data may include retrieving the compressed representation and generating time-varying data from the compressed representation that is substantially similar to the original data.

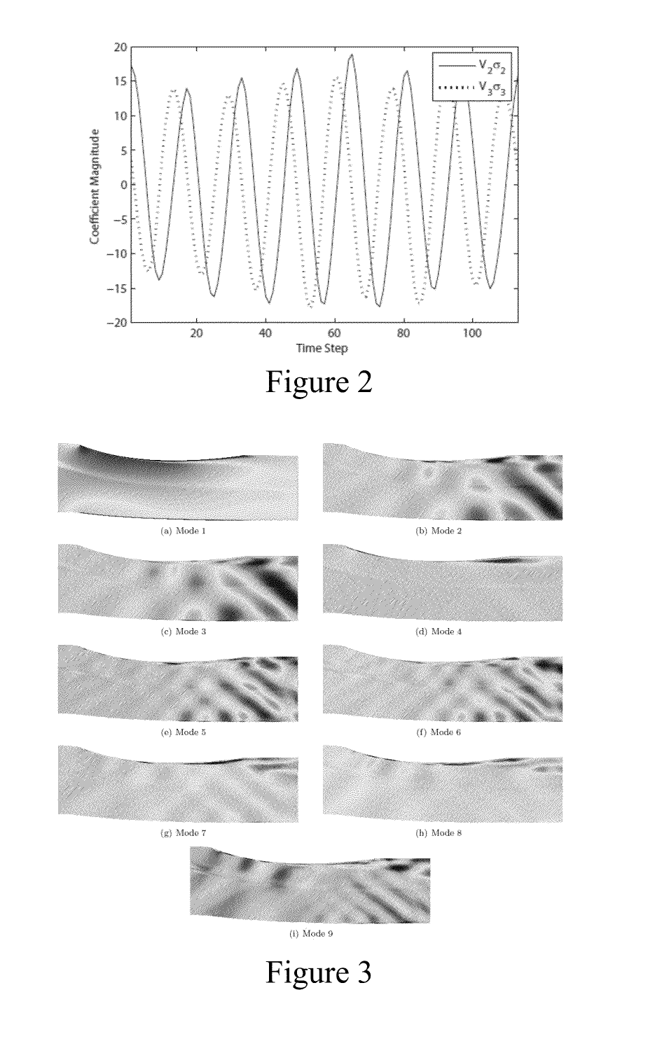

FIG. 2 is a graph depicting example expansion coefficients as a function of the time step in accordance with the present invention. The depicted graph shows the expansion coefficients as a function of time step for the second and third POD modes of a deswirler dataset. FIG. 3 is a set of intensity plots depicting the first nine POD modes for the same deswirler dataset.

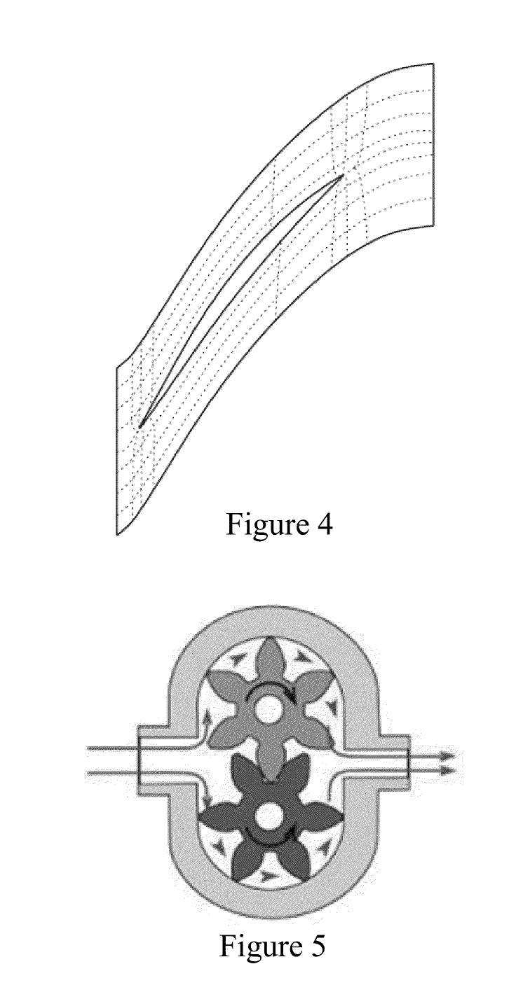

FIG. 4 is a perspective view illustration depicting the concept of sub-domain partitioning in accordance with the present invention. The method shown in FIG. 1 can be made more efficient and accurate by dividing the computational domain of interest into regions or sub-domains. The sub-domains are then independently analyzed using the operations depicted in FIG. 1.

One reason for applying domain partitioning is similar to the reasoning behind grid refinement. In areas of the computational domain where more dynamic or high gradient phenomena are located, it is beneficial to increase the resolution of the grid to promote greater accuracy in modeling the phenomena. Likewise, by partitioning the domain into smaller sub-domains, proper orthogonal decomposition provides basis vectors that model the variation specific to that sub-domain.

A second reason for applying domain partitioning is that the methods disclosed herein are more effective when the grid points in the data set are more correlated i.e., have similar dominant frequencies, mean values, phase, or the like. For instance, referring to FIG. 5, some physical phenomenon may be highly correlated (i.e., coherent) in multiple regions that spatially distant and disjoint. For example, the inlet and outlet of the depicted pump would likely be more correlated and coherent with each other that with other regions. Consequently including the inlet and outlet in the same sub-domain that leverages the same basis vectors may result in better compression fidelity and/or higher compression ratios despite the fact that the inlet and outlet are spatially separated and spatially disjoint.

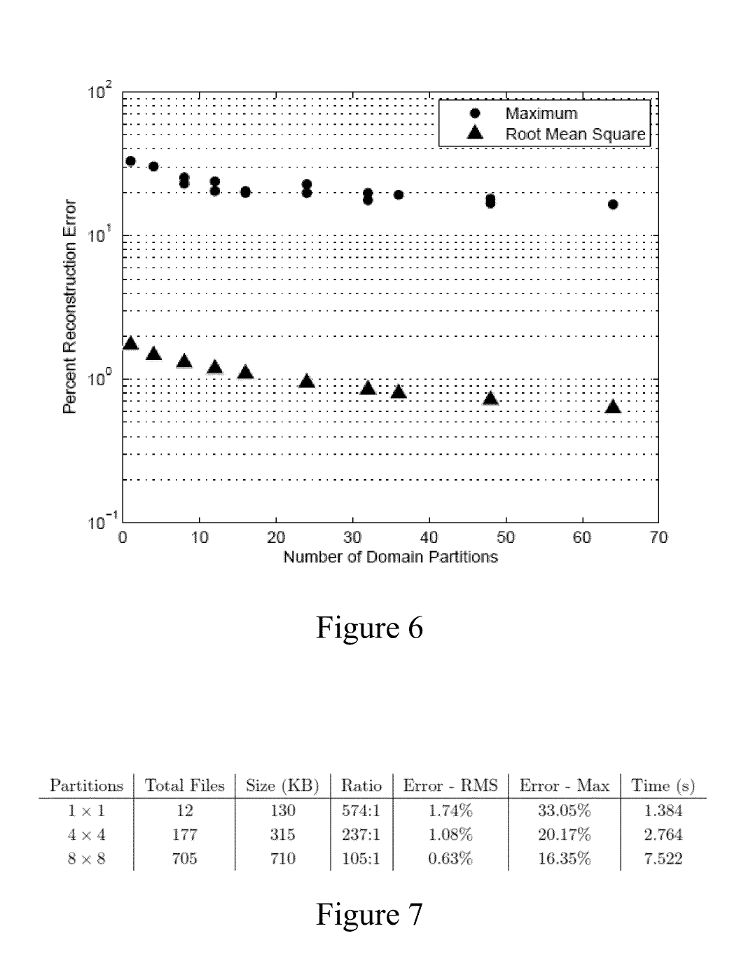

FIG. 6 is a graph depicting the effect of sub-domain partitioning on reconstruction error in accordance with the present invention. The rotor blade domain shown in FIG. 4 was analyzed for the effect that partitioning has on reconstructing a flow field. In this case, the number of modes used in each sub-domain (i.e., 9) was the same as that used in the full domain. The domain was partitioned based on the number of grid (meshing) points alone with no other considerations. Consequently, the physical size of the sub-domains varied according to mesh spacing. The number of divisions were varied from one to eight for both the rows and columns of the computational domain. The highest number of divisions observed for reconstruction accuracy was 64 from the 8×8 example shown in FIG. 4. The partitioned domains were observed for both RMS and maximum error. As is shown, both RMS and maximum error were significantly improved.

FIG. 7 is a table depicting the effect of sub-domain partitioning on various performance metrics for the compression example discussed above. FIG. 7 charts the RMS and maximum percent reconstruction error based on the total number of domain partitions (sub-domains). Reconstructing a single complete (i.e., 1×1) domain with nine modes resulted in an RMS error of 1.74% and maximum error of 33.01%. Compared to the 1×1 full domain reconstructions, the 8×8 case reduced the RMS and maximum errors by 63 and 50 percent, respectively.

The methods presented herein may be implemented (in whole or in part) as a processor configured with software that is partitioned into one or more modules that collectively provide the specified functionality. Each module may comprise one or more physical or logical blocks of computer instructions which may, for instance, be organized as an object, procedure, or function. Nevertheless, the executables of an identified module need not be physically located together, but may comprise disparate instructions stored in different locations which, when joined logically together, enable the module to achieve the intended purpose for the module.

Indeed, the executable code of a module may be a single instruction, or many instructions, and may even be distributed over several different code segments, among different programs, and across several memory devices. Similarly, operational data may be identified and illustrated herein within modules, and may be embodied in any suitable form and organized within any suitable type of data structure. The operational data may be collected as a single data set, or may be distributed over different locations including over different storage devices.

Reference throughout this specification to “one embodiment,” “an embodiment,” or similar language means that a particular feature, structure, or characteristic described in connection with the embodiment is included in at least one embodiment of the present invention. Thus, appearances of the phrases “in one embodiment,” “in an embodiment,” and similar language throughout this specification may, but do not necessarily, all refer to the same embodiment.

Reference to a computer readable medium or computer program product may take any tangible non-transitory form capable of enabling execution of a program of machine-readable instructions on a digital processing apparatus. For example, a computer readable medium may be embodied by a flash drive, compact disk, digital-video disk, a magnetic tape, a magnetic disk, a punch card, flash memory, integrated circuits, or other digital processing apparatus memory device. A digital processing apparatus such as a computer may store program codes, associated data, and the like on the computer readable medium that when retrieved enable the digital processing apparatus to execute the functionality specified by the modules. The digital processing apparatus may be integrated into a computing system that leverages the digital processing apparatus and computer program product.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art will recognize, however, that the invention may be practiced without one or more of the specific details, or with other methods, components, materials, and so forth. In other instances, well-known structures, materials, or operations are not shown or described in detail to avoid obscuring aspects of the invention.

It should also be understood that this description is not intended to limit the invention. On the contrary, the exemplary embodiments are intended to cover alternatives, modifications, and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present exemplary embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

What is claimed is:

1. A method, executed by at least one processor, for compressing time-varying scientific data, the method comprising:
receiving time-varying data corresponding to a physical phenomenon within a domain comprising one or more spatial dimensions;
conducting a proper orthogonal decomposition of the time-varying data to provide basis vectors for the time-varying data;
generating a set of expansion coefficients corresponding to the basis vectors that are most prominent in the time-varying data;
conducting an image compression algorithm on the expansion coefficients to provide a compressed representation of the time-varying data; and
storing the compressed representation of the time-varying data.

2. The method of claim 1, further comprising conducting the image compression algorithm on the basis vectors that are most prominent to provide compressed basis vectors and including the compressed basis vectors in the compressed representation.

3. The method of claim 1, wherein the time-varying data comprises numeric data generated from a physical simulation.

4. The method of claim 1, wherein the time-varying data corresponds to a sub-domain within a larger dataset.

5. The method of claim 1, wherein the time-varying data corresponds to a plurality of coherent sub-domains within a larger dataset.

6. The method of claim 1, further comprising de-trending the time-varying data previous to conducting the proper orthogonal decomposition of the time-varying data.

7. The method of claim 1, wherein the image compression algorithm is JPEG compliant.

8. The method of claim 1, wherein the image compression algorithm comprises a sinusoidal transform or a wavelet transform.

9. The method of claim 1, wherein the sinusoidal transform is selected from a discrete Fourier transform, a discrete cosine transform, and a discrete sine transform.

10. A computer-program product comprising instructions for executing a method for compressing time-varying scientific data, the method comprising:
receiving time-varying data corresponding to a physical phenomenon within a domain comprising one or more spatial dimensions;
conducting a proper orthogonal decomposition of the time-varying data to provide basis vectors for the time-varying data;
generating a set of expansion coefficients corresponding to the basis vectors that are most prominent in the time-varying data;
conducting an image compression algorithm on the expansion coefficients to provide a compressed representation of the time-varying data; and
storing the compressed representation of the time-varying data.

11. The computer-program product of claim 10, wherein the method further comprises conducting the image compression algorithm on the basis vectors that are most prominent to provide compressed basis vectors and including the compressed basis vectors in the compressed representation.

12. The computer-program product of claim 10, wherein the time-varying data comprises numeric data generated from a physical simulation.

13. The computer-program product of claim 10, wherein the time-varying data corresponds to a sub-domain within a larger dataset.

14. The computer-program product of claim 10, wherein the time-varying data corresponds to a plurality of coherent sub-domains within a larger dataset.

15. The computer-program product of claim 10, wherein the method further comprises de-trending the time-varying data previous to conducting the proper orthogonal decomposition of the time-varying data.

16. The computer-program product of claim 10, wherein the image compression algorithm is JPEG compliant.

17. The computer-program product of claim 10, wherein the image compression algorithm comprises a sinusoidal transform or a wavelet transform.

18. The computer-program product of claim 10, wherein the sinusoidal transform is selected from a discrete Fourier transform, a discrete cosine transform, and a discrete sine transform.

19. A computing system comprising one or more processors and a computer-readable medium with instructions encoded thereon for executing a method for compressing time-varying scientific data, the method comprising:
receiving time-varying data corresponding to a physical phenomenon within a domain comprising one or more spatial dimensions;
conducting a proper orthogonal decomposition of the time-varying data to provide basis vectors for the time-varying data;
generating a set of expansion coefficients corresponding to the basis vectors that are most prominent in the time-varying data;
conducting an image compression algorithm on the expansion coefficients to provide a compressed representation of the time-varying data; and
storing the compressed representation of the time-varying data.

20. The computing system of claim 19, wherein the method further comprises conducting the image compression algorithm on the basis vectors that are most prominent to provide compressed basis vectors and including the compressed basis vectors in the compressed representation.
